(19) United States
(12) Patent Application Publication
(10) Pub. No.: US 2026/0147181 A1
(43) Pub. Date: May 28, 2026

(54) MEMS MIRROR ARRAY MODULE

(71) Applicant: Carl Zeiss SMT GmbH, Oberkochen (DE)

(72) Inventors: Andreas-Josef GRIMM, Rainau (DE); Joachim FRIEDL, Oberkochen (DE); Andreas FROMMEYER, Schwaebisch Gmuend (DE); Stefan WALZ, Schwaebisch Gmuend (DE); Thomas WOLFSTEINER, Aalen (DE); Markus HOLZ, Aalen (DE)

(21) Appl. No.: 19/443,423

(22) Filed: Jan. 8, 2026

Related U.S. Application Data
(63) Continuation of application No. PCT/EP2024/068653, filed on Jul. 3, 2024.

(30) Foreign Application Priority Data
Jul. 11, 2023 (DE) 10 2023 118 233.1

(51) Int. Cl. G02B 7/18; G02B 26/08; G02B 26/10; G03F 7/00

(52) U.S. Cl. CPC G02B 7/1815; G02B 26/0833; G02B 26/101; G03F 7/70116; G03F 7/70833; G03F 7/70891; G03F 7/7095; G03F 7/70991

(57) ABSTRACT

A MEMS mirror array module can be used in photolithographic projection exposure apparatuses.

### CROSS-REFERENCE TO RELATED APPLICATIONS

The present application is a continuation of, and claims benefit under 35 USC 120 to, international application No. PCT/EP2024/068653, filed Jul. 3, 2024, which claims benefit under 35 USC 119 of German Application No. 10 2023 118 233.1, filed Jul. 11, 2023. The entire disclosure of each of these applications is incorporated by reference herein.

### FIELD

The disclosure relates to a MEMS mirror array module for use in photolithographic projection exposure apparatuses.

### BACKGROUND

Photolithography is used for producing microstructured component parts, such as for example integrated circuits. The projection exposure apparatus used in the process comprises an illumination system and a projection system. The image of a mask (also referred to as a reticle) illuminated by the illumination system is projected so as to reduce the size of the former onto a substrate, for example a silicon wafer, which is coated with a light-sensitive layer and arranged in the image plane of the projection system, using the projection system in order to transfer the mask structure to the light-sensitive coating of the substrate.

In general, two facet mirrors are arranged in the beam path between the actual exposure radiation source and the mask to be illuminated in the case of illumination systems, for example of projection exposure apparatuses designed for the EUV range, i.e. for exposure wavelengths from 5 nm to 30 nm, and the mirrors allow homogenization of the radiation in a manner substantially comparable to the principle of a fly's eye condenser.

The closer facet mirror in the beam path of the exposure radiation source is often a so-called field facet mirror, and the other facet mirror is a so-called pupil facet mirror.

In order to be able to produce different intensity and/or angle of incidence distributions during the illumination of the mask, it is known for the facets of at least one of the two facet mirrors—for example those of the field facet mirror—to be formed from one or more micromirrors that are electromechanically pivotable on an individual basis. The same is correspondingly disclosed e.g. in WO 2012/130768 A2.

In order to be able to achieve a small size of the individual micromirrors, it is known practice to design groups of micromirrors in the form of what is known as a MEMS mirror array, i.e. a mirror array made of microelectromechanical systems (MEMS).

In a MEMS mirror array, each of a multiplicity of small mirror elements is mounted so as to be individually movable vis-à-vis a joint base. For each mirror element, at least one actuator is provided and enables the mirror element to be adjusted along a respectively predefined degree of freedom. The mirror elements are frequently pivotable about two axes extending perpendicular to each other and parallel to the base, in which case enough actuators are then also provided to enable the mirror element to pivot about precisely these axes independently of each other. For the individual mirror elements, sensors can also be provided and enable the position of the mirror element to be determined relative to the base, so that the alignment of the mirrors can be monitored. An embodiment for the mirrors of a MEMS mirror array is described in DE 10 2015 204 874 A1.

A method for producing a micromirror or a MEMS mirror array comprising a plurality of such micromirrors is disclosed—together with further details relating to a possible configuration of the micromirror—in DE 10 2015 220 018 A1.

In the case of the intended use in photolithography as already mentioned at the outset, a MEMS mirror array is used in the region of the illumination system. In this case, high-energy radiation is incident on the mirror surfaces of the MEMS mirror array and reflected off there in the respective desired direction; however, some of the incident radiation is also absorbed and hence introduced into the MEMS structure as heat. Together with the heat input of the electronic components of the MEMS structure and the fact that MEMS mirror arrays of photolithographic illumination systems—especially in the EUV range—are commonly arranged in vacuo such that heat dissipation by convection is generally ruled out, it is possible that elevated temperatures may arise in the MEMS mirror arrays during operation of such an illumination system and may reduce the service life of both the reflective coating and the electronic and electromechanical components.

### SUMMARY

The present disclosure seeks to provide an improved MEMS mirror array module.

In an aspect, the disclosure provides a MEMS mirror array module comprising a MEMS mirror array structure arranged on a rewiring substrate, and an interface element which is arranged on the side of the rewiring substrate facing away from the MEMS mirror array structure and serves to secure the MEMS mirror array module to a superordinate assembly, wherein a cavity is provided between the rewiring substrate and the interface element and the walls thereof are thermally conductively connected to at least the rewiring substrate, and a fluid line for conducting heat transfer fluid is guided with thermally conductive contact along the walls, with its at least one end being guided out of the MEMS mirror array module through the interface element.

Firstly, some terms used in connection with the disclosure are explained.

A substance or material is “thermally conductive” if it is suitable for transporting heat without a simultaneous substance transport, with thermal conductivity being given at any temperature difference and at any temperatures occurring in expected operating states. A substance is considered to be thermally conductive at least when the thermal conductivity at 0° C. is greater than or equal to

$$4 \frac{W}{m \cdot K} ,$$

such as greater than or equal to

$$15 \frac{W}{m \cdot K} ,$$

and does not drop below

$$1 \frac{W}{m \cdot K}$$

at least for all expected operating temperatures occurring in the substance.

In a sense, the disclosure can include a not atypical known construction of MEMS mirror array modules. It can comprise the MEMS structure which forms the actual MEMS mirror array and has a multiplicity of mirror elements, each of which is pivotable about at least one axis, in general about two axes running perpendicular to each other, provided with a reflective coating and can be pivoted on an individual basis by actuators which are also part of the MEMS mirror array structure. Sensors which can be used to measure the respective angular position of the individual mirror elements may also be provided. The MEMS mirror array structure may additionally comprise application-specific integrated circuits (ASICs), for example circuits for targeted pivot positions of individual mirror elements. Additional sensors, for example temperature sensors, may also be formed and provided as an application-specific integrated circuit.

The MEMS mirror array structure can be arranged on a rewiring substrate and securely connected to the latter. The rewiring substrate, which is often manufactured on a silicon basis, can serve for the bonding—i.e. the contacting of the electrical contacts—the MEMS mirror array structure and the conversion of the contacts on the MEMS mirror array structure into such contacts, generally larger contacts, onto which control and supply cables can be plugged or soldered. Furthermore, the structural integrity of the MEMS mirror array structure can be ensured by the rewiring substrate, even under mechanical loads. Finally, the rewiring substrate also can serve to dissipate heat from the MEMS structure, wherefore the rewiring substrate can be thermally conductive in general.

An interface element can be provided on the side of the rewiring substrate facing away from the MEMS mirror array structure. This interface element can allow the MEMS mirror array module to be secured to a superordinate assembly, for example to a carrier plate of a facet mirror assembly for the illumination system in a projection exposure apparatus. In this case, the interface element may be embodied as desired and for example in view of the envisaged use and the connection technology provided in the process. In general, the material for the interface element may also be chosen as desired. However, at least in certain known systems, use is often made of a thermally conductive material in order to allow heat conduction from the MEMS mirror array structure into the superordinate assembly via the rewiring substrate and the interface element. The supply and control lines for the MEMS mirror array structure are often also guided through the interface element into the superordinate assembly, in order to be suitably connected there.

A concept is to provide a cavity between the rewiring substrate and the interface element, with the walls of the cavity being thermally conductively connected to the rewiring substrate. In other words, heat can thus flow from the rewiring substrate into the walls of the cavity in the case of a temperature difference, wherein the rewiring substrate itself may also form a portion of the cavity walls. The cavity may (also) be used for various purposes, for example for connecting control and supply lines for the MEMS mirror array structure. However, according to the disclosure, provision can be made in any case for a fluid line serving to conduct a heat transfer fluid to be guided along the walls. A heat transfer fluid guided through the fluid line can be in thermally conductive contact in this case, i.e. both the fluid line itself, but also the contact region of the fluid line with the walls can be thermally conductive. Thus, heat conduction can occur from the walls to the heat transfer fluid in the case of a temperature difference between the portion of the walls adjoined by the fluid line and the heat transfer fluid guided in the latter.

At least one end of the fluid line can be guided out of the MEMS mirror array module through the interface element. In this case, the fluid line may protrude from the interface element or else end in the region of an outer surface of the interface element. The fluid line may further be configured in such a way that a direct connection of further fluid line sections is possible. To this end, the fluid line may comprise parts of a fluid coupling mechanism in the region of an outer surface of the interface element or else be suitably designed for simple and tight link of a further fluid line section, for example comprise a flange.

As a result of a configuration of a MEMS mirror array module according to the disclosure, heat introduced into or arising in the MEMS mirror array structure can be transferred purely by heat conduction into a heat transfer fluid situated in the fluid line via the rewiring substrate, the walls of the cavity thermally conductively connected thereto and the fluid line thermally conductively adjacent to the walls. If the temperature of the heat transfer fluid in the fluid line in the region adjacent to the walls is lower than that of the MEMS mirror array structure, there can be a corresponding heat flow, and heat is dissipated from the MEMS mirror array structure.

In order to help ensure a permanent thermally conductive contact between the fluid line and the walls, provision may be made for the fluid line to be integrally bonded to the walls. In order to furthermore ensure good heat conduction between the walls and the fluid line, the material used for the integral bond can also be thermally conductive. In this context, the integral bond can be designed, or the utilized material can be chosen, in such a way that the integral bond does not fail on account of stresses at the joint owing to different coefficients of thermal expansion of the fluid line and the components forming the walls of the cavity. Self-evidently, the stresses in question may also be reduced by structural measures and by matching the coefficients of thermal expansion of the fluid line and the components forming the walls of the cavity.

The material used for the integral bond may be solder, from which it is immediately apparent that the fluid line is secured to the walls by soldering. It is often desirable to use high-melting solder for brazing at temperatures above 450° C. The use of a corresponding solder can help ensure that the integral bond does not fail or become soft at the temperatures usually to be expected at the joint during the described desired heat conduction.

In an alternative to that, a thermally conductive adhesive may be used as the material for the integral bond. In order to ensure the heat conduction, the adhesive may e.g. comprise silver particles and/or particles of hexagonal boron nitride.

It is also possible to produce the desired integral bond by sintering with thermally conductive material. In this case, the use of silver sintering is desirable since this results in good heat conduction properties.

It is often desirable for a metallic coating to be applied to at least that portion of the walls along which the fluid line is guided, especially if the integral bond is to be implemented by soldering or sintering but the walls in the region adjacent to the fluid line are not directly suitable for this purpose. The metallic material for the coating may be chosen for example with regard to the solder or sintered material to be used. Furthermore, the coating is thermally conductive, but this is generally the case for a metallic coating.

The walls along which the fluid line are guided may be parallel and/or perpendicular to the side of the rewiring substrate facing away from the MEMS mirror array structure.

If the fluid line extend parallel to the rewiring substrate, the fluid line may be directly adjacent to the rewiring substrate-provided the rewiring substrate forms a portion of the walls of the cavity. In that case, the heat conduction path from the MEMS mirror array structure to the fluid line or to the heat transfer fluid located in the latter can be short.

Having the fluid line extend along the walls perpendicular to the rewiring substrate may be desirable for the production of the MEMS mirror array module-especially if the walls in question are not part of the rewiring substrate. The fluid line may then be arranged on the walls, for example through the opening of the cavity which is concealed by the rewiring substrate in the later final state, and may optionally be secured there by integral bonding, with the cavity only being sealed subsequently.

In general, the cavity according to the disclosure may already be formed by the components of certain known systems, for example by the rewiring substrate and/or the interface element. However, it has been found to be desirable for the cavity and the walls thereof to be formed at least in part by a spacer element arranged between the rewiring substrate and the interface element. If the spacer element form a portion of the walls of the cavity along which the fluid line is guided, the spacer element can be configured to be thermally conductive at least in this region in order to ensure the thermally conductive inventive link to the rewiring substrate. The spacer element may be manufactured from the same material as the rewiring substrate. The spacer element can be made of ceramic.

It is desirable for the fluid line to be guided out of the MEMS mirror array module through the interface element in a direction parallel to the surface normal of the MEMS structure. In that case, the fluid line can be guided out of the MEMS mirror array module in the direction in which the MEMS mirror array module is inserted into a superordinate assembly, and this can simplify the connection to further fluid line sections.

The fluid line in the MEMS mirror array module may be a fluid line loop. In that case, heat transfer fluid may be guided through the fluid line loop from the outside. To this end, the fluid line in each case can comprise an inlet guided through the interface element and an outlet for connection to a heat transfer fluid circuit.

Alternatively, the fluid line may be a closed heat pipe in which heat is transported from a warmer end—generally the end located in the cavity—to the cooler end purely on account of processes taking place in the interior of the heat pipe. If a temperature at the end of the heat pipe that is not arranged in the cavity can be ensured to be lower than in the cavity, then it is ultimately possible for heat to be dissipated from the MEMS mirror array structure. It is desirable for a capillary wick structure to be provided in the interior of the heat pipe, ensuring that it truly is a heat pipe. Independently thereof, the fluid in the interior of the heat pipe can be adapted to the temperatures to be expected during the use of the MEMS mirror array module, but this can be done by a person skilled in the art.

It is desirable for the MEMS mirror array module to comprise at least one application-specific integrated circuit for measuring the temperature in the region of the circuit. Using such a circuit, the temperature can be measured at a point in the MEMS mirror array module defined by the position of the circuit. This information may merely be recorded for monitoring purposes. However, it is also possible to use the information in one or more suitably designed application-specific integrated circuits for the purpose of active temperature control. In this case, the temperature may be influenced for example by adapting the temperature and/or flow rate of heat transfer fluid through the fluid line or by adapting the temperature at the remote end of a fluid line in the form of a heat pipe as seen from the cavity. For example, a corresponding application-specific integrated circuit may be provided directly in the MEMS mirror array structure or else be arranged in the cavity of the MEMS mirror array module. The configuration and the design options for producing corresponding circuits are familiar to a person skilled in the art.

The fluid line can be made of steel or copper. The final choice of the material can be made in view of the corrosion resistance in relation to the heat transfer fluid provided.

### BRIEF DESCRIPTION OF THE DRAWINGS

The disclosure will now be described by way of example on the basis of certain embodiments with reference to the accompanying drawings, in which:

FIG. 1 shows a schematic illustration of a photolithographic projection exposure apparatus comprising MEMS mirror array modules according to the disclosure;

FIG. 2 shows a schematic illustration of a first exemplary embodiment of a MEMS mirror array module according to the disclosure;

FIG. 3 shows a schematic illustration of a second exemplary embodiment of a MEMS mirror array module according to the disclosure; and

FIG. 4 shows a schematic illustration of a third exemplary embodiment of a MEMS mirror array module according to the disclosure.

### DETAILED DESCRIPTION

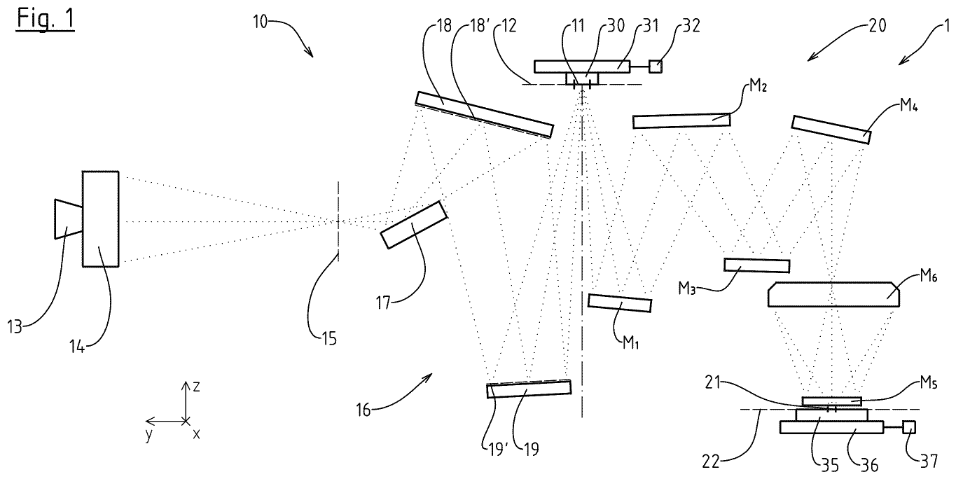

FIG. 1 illustrates a schematic meridional section of a photolithographic projection exposure apparatus 1. In this case, the projection exposure apparatus 1 comprises an illumination system 10 and a projection system 20.

An object field 11 in an object plane or reticle plane 12 is illuminated with the aid of the illumination system 10. For this purpose, the illumination system 10 comprises an exposure radiation source 13, which, in the illustrated exemplary embodiment, emits illumination radiation at least comprising used light in the EUV range, i.e. with a wavelength of between 5 nm and 30 nm for example. The exposure radiation source 13 can be a plasma source, for example an LPP (laser produced plasma) source or a GDPP (gas discharge produced plasma) source. It can also be a synchrotron-based radiation source. The exposure radiation source 13 can also be a free electron laser (FEL).

The illumination radiation emerging from the exposure radiation source 13 is initially focused in a collector 14. The collector 14 may be a collector with one or more ellipsoidal and/or hyperboloidal reflection surfaces. The illumination radiation can be incident on the at least one reflection surface of the collector 14 with grazing incidence (GI), i.e. at angles of incidence of greater than 45°, or with normal incidence (NI), i.e. at angles of incidence of less than 45°. The collector 14 can be structured and/or coated on the one hand for optimizing its reflectivity for the used radiation and on the other hand for suppressing extraneous light.

Downstream of the collector 14, the illumination radiation propagates through an intermediate focus in an intermediate focal plane 15. If the illumination system 10 is constructed in a modular design, the intermediate focal plane 15 can be used, in general, for the separation—including the structural separation—of the illumination system 10 into a radiation source module, comprising the exposure radiation source 13 and the collector 14, and the illumination optics unit 16 described below. In the case of a corresponding separation, radiation source module and illumination optics unit 16 then jointly form a modularly constructed illumination system 10.

The illumination optics unit 16 comprises a deflection mirror 17. The deflection mirror 17 can be a plane deflection mirror or alternatively a mirror with a beam-influencing effect going beyond the pure deflection effect. In an alternative to that or in addition, the deflection mirror 17 can be embodied as a spectral filter that separates a used light wavelength of the illumination radiation from extraneous light having a wavelength that deviates therefrom.

The deflection mirror 17 is used to deflect the radiation emanating from the exposure radiation source 13 to a first facet mirror 18. If—as in the present case—the first facet mirror 18 is arranged in a plane of the illumination optics unit 16 which is optically conjugate to the reticle plane 12 as a field plane, this facet mirror is also referred to as a field facet mirror.

The first facet mirror 18 comprises a multiplicity of micromirrors 18′ that are individually pivotable about two mutually perpendicular axes in each case, for the purpose of controllably forming facets each of which can have an orientation sensor (not depicted) for ascertaining the orientation of the micromirror 18′. The first facet mirror 18 is thus a microelectromechanical system (MEMS system), as also described in DE 10 2008 009 600 A1, for example.

A second facet mirror 19 is arranged downstream of the first facet mirror 18 in the beam path of the illumination optics unit 16, with the result that this yields a doubly faceted system, the fundamental principle of which is also referred to as a fly's eye integrator. If the second facet mirror 19—as in the illustrated exemplary embodiment—is arranged in a pupil plane of the illumination optics unit 16, it is also referred to as a pupil facet mirror.

However, the second facet mirror 19 can also be arranged at a distance from a pupil plane of the illumination optics unit 16, as a result of which a specular reflector arises from the combination of the first and the second facet mirror 18, 19, for example as described in US 2006/0132747 A1, EP 1 614 008 B1 and U.S. Pat. No. 6,573,978.

The second facet mirror 19 need not in general be constructed from pivotable micromirrors but rather can comprise individual facets formed from one mirror or a manageable number of mirrors which are significantly larger than micromirrors, which facets are either stationary or tiltable only between two defined end positions. It is however—as illustrated—also possible, in the second facet mirror 19, to provide a microelectromechanical system having a multiplicity of micromirrors 19′ that are individually pivotable about two mutually perpendicular axes in each case, each can comprise an orientation sensor.

The individual facets of the first facet mirror 18 are imaged into the object field 11 with the aid of the second facet mirror 19, with this typically only being approximate imaging. The second facet mirror 19 can be the last beam-shaping mirror or else actually the last mirror for the illumination radiation in the beam path upstream of the object field 11.

In each case one of the facets of the second facet mirror 19 is assigned to exactly one of the facets of the first facet mirror 18 for the purpose of forming an illumination channel for illuminating the object field 11. This may for example result in illumination according to the Köhler principle.

The facets of the first facet mirror 18 are imaged overlaid on one another by way of a respective assigned facet of the second facet mirror 19, for the purpose of illuminating the object field 11. Here, the illumination of the object field 11 is as homogeneous as possible. It can have a uniformity error of less than 2%. Field uniformity can be achieved by overlaying different illumination channels.

By selecting the ultimately used illumination channels, which is possible without problems by way of a suitable setting of the micromirrors 18′ of the first facet mirror 18, it is still possible to set the intensity distribution in the entrance pupil of the projection system 20 described below. This intensity distribution is also referred to as illumination setting. Incidentally, it may be desirable here to arrange the second facet mirror 19 not exactly in a plane that is optically conjugate to a pupil plane of the projection system 20. For example, the pupil facet mirror 19 can be arranged tilted relative to a pupil plane of the projection system 20, as is described in DE 10 2017 220 586 A1, for example.

In the arrangement of the components of the illumination optics unit 16 as illustrated in FIG. 1, however, the second facet mirror 19 is arranged in an area conjugate to the entrance pupil of the projection system 20. Deflection mirror 17 and the two facet mirrors 18, 19 are arranged tilted both vis-à-vis the object plane 12 and vis-à-vis one another in each case.

In an alternative embodiment (not illustrated) of the illumination optics unit 16, a transfer optics unit comprising one or more mirrors can additionally be provided in the beam path between the second facet mirror 19 and the object field 11. The transfer optics unit may for example comprise one or two normal-incidence mirrors (NI mirrors) and/or one or two grazing-incidence mirrors (GI mirrors). Using an additional transfer optics unit, it is possible for example to take account of different poses of the entrance pupil for the tangential and for the sagittal beam path of the projection system 20 described below.

It is alternatively possible for the deflection mirror 17 illustrated in FIG. 1 to be dispensed with, for which purpose the facet mirrors 18, 19 can then be suitably arranged vis-à-vis the radiation source 13 and the collector 14.

The object field 11 in the reticle plane 12 is transferred to the image field 21 in the image plane 22 with the aid of the projection system 20.

For this purpose, the projection system 20 comprises a plurality of mirrors Mᵢ, which are consecutively numbered in accordance with their arrangement in the beam path of the projection exposure apparatus 1.

In the example depicted in FIG. 1, the projection system 20 comprises six mirrors M₁ to M₆. Alternatives with four, eight, ten, twelve or any other number of mirrors M₁ are likewise possible. The penultimate mirror M₅ and the last mirror M₆ each have a passage opening for the illumination radiation, as a result of which the illustrated projection system 20 is a doubly obscured optical unit. The projection system 20 has an image-side numerical aperture that is greater than 0.3 and can also be greater than 0.6 and can be for example 0.7 or 0.75.

The reflection surfaces of the mirrors M₁ can be in the form of freeform surfaces without an axis of rotational symmetry. However, the reflection surfaces of the mirrors M₁ can alternatively also be designed as aspherical surfaces with exactly one axis of rotational symmetry of the reflection surface shape. Like the mirrors of the illumination optics unit 16, the mirrors M₁ may have highly reflective coatings for the illumination radiation. These reflective coatings can be designed as multilayer coatings, for example with alternating layers of molybdenum and silicon.

The projection system 20 has a large object-image shift in the y-direction between a y-coordinate of a center of the object field 11 and a y-coordinate of the center of the image field 21. This object-image shift in the y-direction can be of approximately the same magnitude as a z-distance between the object plane 12 and the image plane 22.

For example, the projection system 20 may be designed to be anamorphic, i.e. it has different imaging scales βₓ, β_{y} in the x- and y-directions for example. The two imaging scales βₓ, β_{y} of the projection system 20 can be (βₓ, β_{y})=(+/−0.25,/+−0.125). An imaging scale β of 0.25 corresponds here to a reduction with a ratio 4:1, while an imaging scale β of 0.125 results in a reduction with a ratio of 8:1. A positive sign in the case of the imaging scale β means imaging without image inversion; a negative sign means imaging with image inversion.

Other imaging scales are likewise possible. Imaging scales βₓ, β_{y} with the same sign and the same absolute magnitude in the x- and y-directions are also possible.

The number of intermediate image planes in the x-direction and in the y-direction in the beam path between the object field 11 and the image field 21 can be the same or different, depending on the embodiment of the projection system 20. Examples of projection systems 20 with different numbers of such intermediate images in the x-direction and y-direction are known from US 2018/0074303 A1.

For example, the projection system 20 can comprise a homocentric entrance pupil. The latter may be accessible. However, it may also be inaccessible.

A reticle 30 (also referred to as mask) arranged in the object field 11 is exposed by the illumination system 10 and transferred by the projection system 20 onto the image plane 21. The reticle 30 is held by a reticle holder 31. The reticle holder 31 is displaceable for example in a scanning direction by way of a reticle displacement drive 32. In the exemplary embodiment illustrated, the scanning direction runs in the y-direction.

A structure on the reticle 30 is imaged onto a light-sensitive layer of a wafer 35 arranged in the region of the image field 21 in the image plane 22. The wafer 35 is held by a wafer holder 36. The wafer holder 36 is displaceable for example in the y-direction by way of a wafer displacement drive 37. The displacement, firstly, of the reticle 30 by way of the reticle displacement drive 32 and, secondly, of the wafer 35 by way of the wafer displacement drive 37 may be implemented so as to be synchronized with one another.

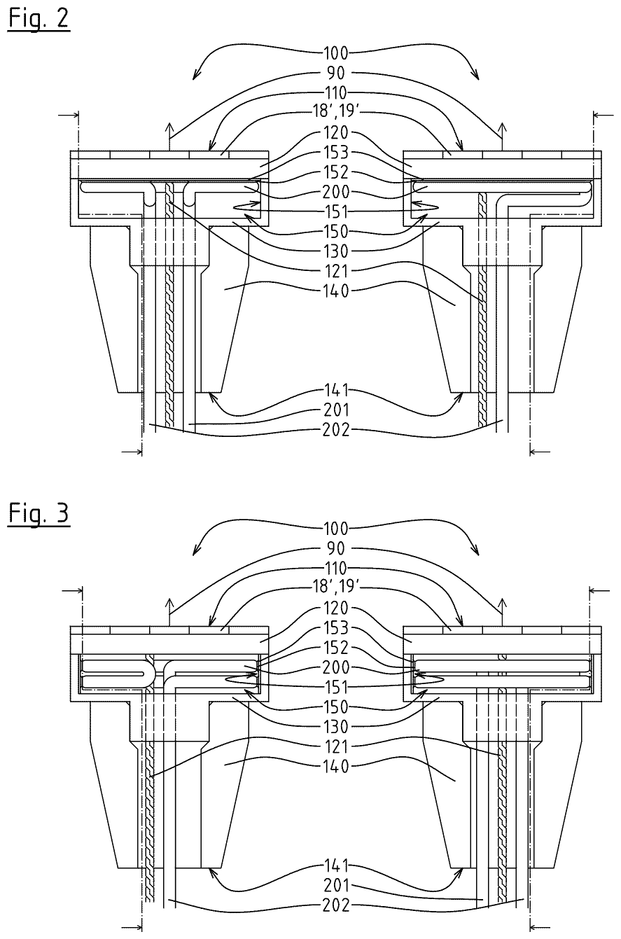

Certain features of the projection exposure apparatus 1 illustrated in FIG. 1, or its illumination system 10, are generally known. However, as disclosed herein, the first and/or second facet mirror 18, 19 in each case comprise a plurality of MEMS mirror array modules 100 according to the disclosure (cf. FIGS. 2 to 4), with the MEMS mirror array modules 100 each comprising a plurality of micromirrors 18′, 19′. The individual MEMS mirror array modules 100 are secured to a superordinate assembly in order to jointly form the facet mirrors 18, 19 schematically depicted in FIG. 1. In addition to mechanical securing, the superordinate assembly also provides any desired link of the individual mirror array modules 100, for example to control electronics and/or cooling circuits.

FIG. 2 schematically illustrates a first exemplary embodiment of a MEMS mirror array module 100 according to the disclosure. The illustration here is in the form of two sectional views, the lines of intersection of which are identified in the respective other view. Hatching of the cut bodies was omitted for reasons of clarity.

The MEMS mirror array module 100 comprises the MEMS mirror array structure 110, which is used with the micromirrors 18′, 19′, and the mechanics and actuators for the controllable pivotability thereof. Sensors for ascertaining the angular positions of the individual micromirrors 18′, 19′ may also be provided. The MEMS mirror array structure 110 is known from, for example, DE 10 2015 204 874 A1, DE 10 2015 220 018 A1 and DE 10 2008 009 600 A1. A detailed explanation of MEMS mirror array structure 110 can therefore be omitted in the present case.

The MEMS mirror array structure 110 is secured to a thermally conductive rewiring substrate 120, which can comprise silicon. In this, the MEMS mirror array structure 110 is connected or bonded to the rewiring substrate 120 not only in a thermally conductive manner but also in a selectively electrical manner in order to convert the electrical contacts of the MEMS mirror array structure 110 provided for operation into electrical contacts to which e.g. electrical control and supply lines 121 can be connected. Moreover, the rewiring substrate 120 provides the MEMS mirror array structure 110 with structural integrity, which the MEMS mirror array structure 110 possibly might not have to a sufficient extent on its own.

A spacer element 130, which is likewise manufactured from silicon or from ceramic and thus also thermally conductive, is connected to the rewiring substrate 120 in a thermally conductive manner. On the side of the spacer element 130 facing away from the rewiring substrate 120, the spacer element is connected to an interface element 140.

Together with the rewiring substrate 120, the spacer element 130 forms a cavity 150, the walls 151 of which are formed in part by the rewiring substrate 120 and in part by the spacer element 130. Since a portion of the walls is formed by the rewiring substrate 120 itself and the remainder of the walls is formed from the spacer element 130 thermally conductively connected thereto, all of the walls 151 of the cavity may be regarded as connected to the rewiring substrate 120 in a thermally conductive manner.

The interface element 140 is designed to secure the MEMS mirror array module 100 to a superordinate assembly. In the exemplary embodiment illustrated, the interface element 140 is of conical form such that it can be inserted into suitable openings in a carrier plate. It extends parallel to the surface normal of the MEMS mirror array structure 110, the surface normal being indicated by arrow 90. The electrical control and supply lines 121 are guided to the outside through the top surface 141 of the interface element 140 such that the control and supply lines 121, after prior threading into the suitable opening of a carrier plate, generally do not impede the subsequent insertion of the MEMS mirror array module 100 therein.

The MEMS mirror array module 100 also comprises a fluid line 200. The fluid line 200 takes the form of a fluid line loop, with the inlet 201 and the outlet 202 of the fluid line loop being guided out of the MEMS mirror array module 100 through the interface element 140 in a manner parallel to the surface normal 90 of the MEMS mirror array structure 110 such that they yield the features explained in the context of the electrical control and supply lines 121 when the MEMS mirror array module 100 is inserted into an opening provided therefor in a superordinate assembly.

The fluid line 200 extends into the cavity 150 and is guided there in the form of a loop along the walls 151 of the cavity 150—more precisely the portion of the walls 151 formed by the rewiring substrate 120—with thermally conductive contact. In this case, the fluid line 200 is integrally bonded to the aforementioned portion of the walls 151 by brazing. Thus, the material 152 used for the integral bond is thermally conductive solder.

In order to be able to solder the fluid line 200 to the walls 151 or the rewiring substrate 120 manufactured from silicon, the region of the walls 151 in question is provided with a metallic coating 153. The material of metallic coating 153, the material for the integral bond 152 (i.e. the solder) and the material for the fluid line 200 are matched to one another in such a way that a reliable and firm connection emerges over the entire range of temperatures to be expected during the use of the MEMS mirror array module 100 as intended.

If the fluid line 200, or the inlet and outlet 201, 202 thereof, is suitably connected to a heat transfer fluid circuit, for example a cooling circuit, suitable temperature control for the heat transfer fluid leads to a temperature difference between the MEMS mirror array structure 110, which may have an undesirably elevated temperature owing both to inherent heat and to absorbed radiation, and the heat transfer fluid in the region of the fluid line 200 though which it is guided with thermally conductive contact along the walls 151. Since the entire path between the MEMS mirror array structure 110 and the heat transfer fluid in the fluid line 200 is configured to be thermally conductive, it is possible to dissipate heat from the MEMS mirror array structure 110, whereby the temperature in the MEMS mirror array structure 110 can be lowered. In general, reversing the temperature difference can also allow the MEMS mirror array structure 110 to be heated, but this plays virtually no role in practice.

It is possible to actively control the temperature of the MEMS mirror array structure 110. To this end, the MEMS mirror array structure 110 may comprise one or more application-specific integrated circuits, each of which measures the temperature of the MEMS mirror array structure 110. The measured temperature value can then be transmitted via the electrical control and supply lines 121 to a superordinate controller, which then controls the flow rate and/or the temperature of the heat transfer fluid guided through the fluid line 200.

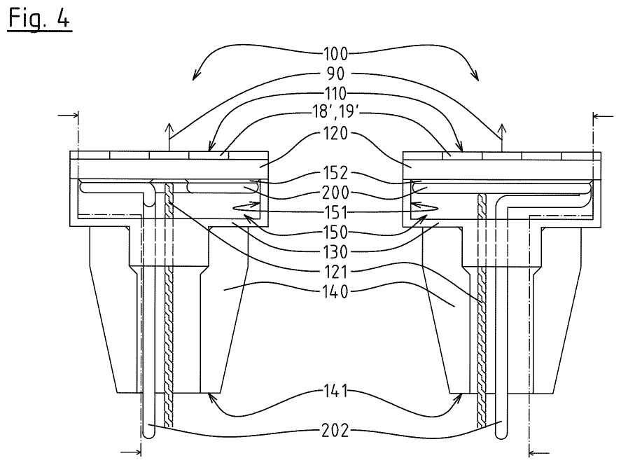

FIG. 3 schematically illustrates a second exemplary embodiment of a MEMS mirror array module 100 according to the disclosure. Both in the illustration and in the construction, the MEMS mirror array module 100 from FIG. 3 largely resembles that from FIG. 2. As a result, reference is made to the above statements and only the differences between the two exemplary embodiments are discussed below.

In the exemplary embodiment according to FIG. 3, the fluid line 200, which is guided in a loop, is guided with thermally conductive contact along that portion of the walls 151 of the cavity 150 in which the walls 151 extend perpendicularly to the underside of the rewiring substrate 120.

Moreover, the integral bond between the fluid line 200 and the portion of the walls 151 is produced by silver sintering, as a result of which the material for the integral bond 152 is sintered silver and thermally conductive.

For the envisaged integral bond, a metallic and hence thermally conductive coating 153 is applied to that region of the walls 151 along which the fluid line 200 is guided with thermally conductive contact since the spacer element 130 forming that portion of the walls 151 of the cavity 150 is made of silicon or ceramic.

FIG. 4 schematically illustrates a third exemplary embodiment of a MEMS mirror array module 100 according to the disclosure. Both in the illustration and in the construction, the MEMS mirror array module 100 from FIG. 4 largely resembles that from FIG. 2. As a result, reference is made to the statements relating to FIG. 2 and only the differences between the two exemplary embodiments are discussed below.

According to FIG. 4, the fluid line 200 is guided in a manner comparable to FIG. 2 along the underside of the rewiring substrate 120 as part of the walls 151 of the cavity 150. However, the fluid line 200 is not a fluid line loop but rather a closed heat pipe-since it is provided in its interior with a capillary wick structure. One end of the fluid line 200 is arranged in the cavity 150, while the other end projects out of the interface element 140. In the installed state of the MEMS mirror array module 100, the end of the fluid line 200 protruding from the interface element 140 may be thermally conductively connected to a heatsink in order to be able to dissipate heat from the MEMS mirror array structure 110 in this way.

The fluid pipe 200 is secured to the walls 151 of the cavity by adhesive as material for the integral bond 152. The adhesive is thermally conductive and comprises silver particles, inter alia for this purpose. A metallic coating 153 (cf. FIGS. 2 and 3) may be omitted in this case.

What is claimed is:

1. A MEMS mirror array module, comprising:
a MEMS mirror array structure;
a rewiring substrate comprising a first side and a second side opposite the first side, the first side of the rewiring substrate supporting the MEMS mirror array structure;
an interface assembly disposed on the second side of the rewiring substrate, the interface assembly configured to secure the MEMS mirror array module to a superordinate assembly;
a cavity between the rewiring substrate and the interface element, the cavity comprising walls that are thermally conductively connected to the rewiring substrate; and
a fluid line configured to have a fluid flow therethrough, the fluid line being in thermally conductive contact with the walls of the cavity, and a portion of the fluid line extending out of the MEMS mirror array module through the interface element.

2. The MEMS mirror array module of claim 1, further comprising a thermally conductive material integrally bonding the fluid line to the walls of the cavity.

3. The MEMS mirror array module of claim 2, wherein the thermally conductive material comprises a solder.

4. The MEMS mirror array module of claim 2, wherein the thermally conductive material comprises a solder configured for brazing at temperatures above 450° C.

5. The MEMS mirror array module of claim 2, wherein the thermally conductive material comprises a thermally conductive adhesive.

6. The MEMS mirror array module of claim 2, wherein the thermally conductive material comprises at least one material selected from the group consisting of silver particles and particles of hexagonal boron nitride.

7. The MEMS mirror array module of claim 2, wherein the integral bond comprises a sintered bond.

8. The MEMS mirror array module of claim 1, further comprising a metallic coating between the fluid line and a portion of the walls of the cavity.

9. The MEMS mirror array module of claim 1, wherein portions of the walls along which the fluid line is guided are parallel and/or perpendicular to the second side of the rewiring substrate.

10. The MEMS mirror array module of claim 1, further comprising a spacer between the rewiring substrate and the interface element, wherein the spacer and the rewiring substrate define the cavity.

11. The MEMS mirror array module of claim 10, wherein the spacer comprises a ceramic.

12. The MEMS mirror array module of claim 1, wherein the portion of the fluid line extending out of the MEMS mirror array module through the interface element is parallel to a surface normal of the MEMS mirror array structure.

13. The MEMS mirror array module of claim 1, wherein the fluid line comprises an inlet through the interface element, the fluid line comprises an outlet configured to connect to a heat transfer fluid circuit, and the fluid line is a loop fluid line.

14. The MEMS mirror array module of claim 1, wherein the fluid line comprises a closed heat pipe.

15. The MEMS mirror array module of claim 14, wherein the closed heat pipe comprises an interior having a capillary wick structure.

16. The MEMS mirror array module of claim 1, further comprising an application-specific integrated circuit configured to measure a temperature in a region of the application-specific integrated circuit.

17. The MEMS mirror array module of claim 16, wherein the application-specific integrated circuit is in the cavity.

18. The MEMS mirror array module of claim 1, wherein the fluid line comprises a material selected from the group consisting of steel and copper.

19. An apparatus, comprising:
an illumination system; and
a projection system,
wherein the illumination system is configured to illuminate an object field in an object plane of the projection system, the projection system is image the object field into an image field of an image plane of the projection system, the illumination system comprises a MEMS mirror array module according to claim 1, and the apparatus is a photolithographic projection exposure apparatus.

20. A method of using a photolithographic projection exposure apparatus comprising an illumination system and a projection system, the method comprising:
using the illumination system to illuminate an object field in an object plane of the projection system; and
using the projection system to image the object field into an image field of an image plane of the projection system,
wherein the illumination system comprises a MEMS mirror array module according to claim 1.
